(19) United States
(12) Patent Application Publication
(10) Pub. No.: US 2026/0344252 A1
(43) Pub. Date: Oct. 29, 2026

(54) DISPLAY DEVICE AND ELECTRONIC APPARATUS INCLUDING THE SAME

(71) Applicant: SAMSUNG DISPLAY CO., LTD., YONGIN-SI (KR)

(72) Inventors: HYUNJAE NA, Yongin-si (KR); YOUNGJIN LEE, Yongin-si (KR); SUNHAENG CHO, Yongin-si (KR); HANSUN RYOU, Yongin-si (KR)

(21) Appl. No.: 19/654,647

(22) Filed: Apr. 22, 2026

(30) Foreign Application Priority Data
Apr. 29, 2025 (KR) 10-2025-0056290

(51) Int. Cl. H10K 59/80; H10K 59/40

(52) U.S. Cl. CPC H10K 59/872; H10K 59/40

(57) ABSTRACT

A display device includes a display panel, a digitizer having a first side disposed on a side surface of the display panel and including a folding portion. A panel support between the display panel and the digitizer. A center bar positioned at a second side of the digitizer. The center bar is positioned to overlap the folding portion in a thickness direction of the display panel. Wing plates respectively disposed at opposite sides of the center bar in a first direction. A gap comprising a separation space is defined between the center bar and each of the wing plates. The folding portion includes a first area including first holes and a second area overlapping the gap in a thickness direction of the display panel.

### CROSS-REFERENCE TO RELATED APPLICATION

This application claims priority under 35 USC §119 to Korean Patent Application No. 10-2025-0056290, filed on Apr. 29, 2025 in the Korean Intellectual Property Office, the disclosure of which is incorporated by reference in its entirety herein.

### 1. TECHNICAL FIELD

Embodiments relate to a display device and an electronic apparatus including the same.

### 2. DISCUSSION OF RELATED ART

Display devices are devices that display moving and/or still images for providing visual information to a user. Flexible display devices that may be transformed into various shapes have become increasingly popular along with the advancement of the information society. Unlike flat panel displays, flexible displays may be foldable, bendable, or rollable like paper. Flexible display devices may be easy to carry and may increase portability and user convenience.

In addition, a display device may include a digitizer that detects an input applied from an external device. For example, a digitizer may be driven by using electromagnetic resonance (EMR).

### SUMMARY

Embodiments of the present disclosure may provide a foldable display device with increased reliability, and an electronic apparatus including the same.

However, the technical objects to be solved by the present disclosure are not limited to the above objects, and other objects that are not described herein will be clearly understood by those skilled in the art from the following descriptions of the present disclosure.

According to an embodiment of the present disclosure, a display device includes a display panel. A digitizer has a first side disposed on a side surface of the display panel. The digitizer comprises a folding portion. A panel support is between the display panel and the digitizer in a thickness direction of the display panel. A center bar is positioned at a second side of the digitizer opposite to the first side of the digitizer. The center bar is positioned to overlap the folding portion in the thickness direction of the display panel. Wing plates are respectively disposed at opposite sides of the center bar in a first direction crossing the thickness direction of the display panel. A gap comprising a separation space is defined between the center bar and each of the wing plates. The folding portion comprises a first area including first holes and a second area overlapping the gap in the thickness direction of the display panel.

In an embodiment, a maximum elongation distance of the first area when the display device is folded may be greater than a maximum elongation distance of the second area when the display device is folded.

In an embodiment, the second area includes second holes having at least one of a different size and shape in a plan view from the first holes.

In an embodiment, a width of each of the first holes in the first direction may be less than a width of each of the first holes in a second direction crossing the first direction, and the second holes may have a same shape as the first holes and may have an area in the plan view that is less than an area in the plan view of the first holes.

In an embodiment, each of the second holes may include an extension portion extending in a second direction crossing the first direction and expansion portions disposed at opposite ends of the extension portion, and in the first direction, a width of at least one area of each of the expansion portions may be greater than a width of the extension portion.

In an embodiment, the expansion portions may have at least one planar shape of a circular shape, an elliptical shape, a triangular shape, or a quadrangular shape.

In an embodiment, an aperture ratio of the first area may be greater than an aperture ratio of the second area.

In an embodiment, the display device may further include an adhesive portion disposed between the panel support and the digitizer, and the adhesive portion may be disposed to overlap at least the gap in the thickness direction of the display panel.

In an embodiment, the adhesive portion may overlap at least the folding portion in the thickness direction of the display panel, and a modulus of the adhesive portion may be less than or equal to about 0.2 MPa.

In an embodiment, the digitizer may include sensing coils disposed between adjacent first holes.

According to an embodiment of the present disclosure, a display device includes a display panel. A digitizer has a first side disposed on a side surface of the display panel. The digitizer comprises a folding portion. A panel support is between the display panel and the digitizer in a thickness direction of the display panel. An adhesive portion is disposed between the panel support and the digitizer. A center bar is positioned at a second side of the digitizer opposite to the first side of the digitizer. The center bar is positioned to overlap the folding portion in the thickness direction of the display panel. Wing plates are respectively disposed at opposite sides of the center bar in a first direction crossing the thickness direction of the display panel. A gap comprising a separation space is defined between the center bar and each of the wing plates. The adhesive portion is disposed to overlap at least the gap in the thickness direction of the display panel.

In an embodiment, the adhesive portion may overlap at least the folding portion in the thickness direction of the display panel, and a modulus of the adhesive portion may be less than or equal to about 0.2 MPa.

In an embodiment, the folding portion may include a first area including first holes and a second area overlapping the gap in a thickness direction of the display panel.

In an embodiment, a maximum elongation distance of the first area when the display device is folded may be greater than a maximum elongation distance of the second area when the display device is folded.

In an embodiment, second holes are disposed in the second area and have at least one of a different size and shape in a plan view from the first holes.

In an embodiment, a width of each of the first holes in the first direction may be less than a width of each of the first holes in a second direction crossing the first direction, and the second holes may have a same shape as the first holes and may have an area in the plan view that is less than an area in the plan view of the first holes.

In an embodiment, each of the second holes may include an extension portion extending in a second direction crossing the first direction and expansion portions disposed at opposite ends of the extension portion, and in the first direction, a width of at least one area of each of the expansion portions may be greater than a width of the extension portion.

In an embodiment, the expansion portions may have at least one planar shape of a circular shape, an elliptical shape, a triangular shape, or a quadrangular shape.

In an embodiment, an aperture ratio of the first area may be greater than an aperture ratio of the second area.

According to an embodiment of the present disclosure, an electronic device includes a display device, a memory storing data information, a processor configured to transmit the data information to the display device, and a power module configured to supply and generate power. The display device includes a display panel. A digitizer has a first side disposed on a side surface of the display panel. The digitizer comprises a folding portion. A panel support is between the display panel and the digitizer in a thickness direction of the display panel. A center bar is positioned at a second side of the digitizer opposite to the first side of the digitizer. The center bar is positioned to overlap the folding portion in the thickness direction of the display panel. Wing plates are respectively disposed at opposite sides of the center bar in a first direction crossing the thickness direction of the display panel. A gap comprising a separation space is defined between the center bar and each of the wing plates. The folding portion comprises a first area including first holes and a second area overlapping the gap in the thickness direction of the display panel.

### BRIEF DESCRIPTION OF THE DRAWINGS

The accompanying drawing portions illustrate embodiments of the present disclosure and, together with the following portion detailed description, serve to provide further understanding of the technical spirit of the present disclosure. However, embodiments of the present disclosure is not to be construed as being limited to the details shown in the drawing portions, in which:

FIG. 1 is a perspective view illustrating an unfolded shape of a display device according to an embodiment of the present disclosure;

FIGS. 2 and 3 are perspective views illustrating a folded shape of the display device of FIG. 1;

FIG. 4 is an exploded perspective view of the display device of FIG. 1;

FIG. 5 is a cross-sectional view illustrating the display device of FIG. 1;

FIG. 6 is a schematic cross-sectional view illustrating a part of a display panel included in the display device of FIG. 1;

FIGS. 7 and 8 are plan views illustrating a digitizer according to an embodiment of the present disclosure;

FIG. 9 is a plan view illustrating an example of area B of FIG. 7;

FIG. 10 is a schematic plan view illustrating another example of area B of FIG. 7;

FIG. 11 is a schematic plan view illustrating another example of area B of FIG. 7;

FIG. 12 is a schematic cross-sectional view illustrating an example of area A of FIG. 5;

FIG. 13 is a schematic cross-sectional view illustrating another example of area A of FIG. 5;

FIG. 14 is a block diagram illustrating an electronic apparatus according to an embodiment of the present disclosure; and

FIG. 15 shows schematic views illustrating electronic apparatuses according to embodiments of the present disclosure.

### DETAILED DESCRIPTION OF EMBODIMENTS

Since the present disclosure can apply various transformations and have various embodiments, example embodiments will be illustrated in the drawings and described in detail in the detailed description. Effects and features of the present disclosure, and methods for achieving them will become clear with reference to embodiments described below in detail together with the drawings. However, the present disclosure is not limited to the embodiments disclosed below and may be implemented in various forms.

In the following embodiments, the terms first, second, and the like do not have limited meaning but are used for the purpose of distinguishing one component from another component.

In the following embodiments, the expressions used in the singular such as “a,” “an,” and “the” are intended to include the plural forms as well, unless the context clearly indicates otherwise.

In the following embodiments, it will be understood that the terms such as “including,” “comprising,” and “having” specify the presence of stated features or components, but do not preclude the presence or addition of one or more other features or components.

In the following embodiments, when a unit, an area, a component, or the like is positioned on or above another part, the present disclosure includes not only a case in which the unit, the area, the component, or the like is positioned directly above the other part, but also a case in which other units, other areas, other component, or the like may be positioned therebetween.

In the following embodiments, unless the terms “connecting” or “coupling” are clearly different in context, the terms “connecting” or “coupling” do not necessarily mean direct and/or fixed connection or coupling of two members, but do not exclude a member positioned between the two members.

In the drawings, components may be exaggerated or reduced in size for convenience of description. For example, the sizes and/or thicknesses of the respective components shown in the drawings may be arbitrarily shown for convenience of description, and thus one or more embodiments are not necessarily limited thereto.

Hereinafter, embodiments of the present disclosure will be described in detail with reference to the accompanying drawings, wherein like reference numerals refer to the same or corresponding components throughout the drawings, and a redundant description thereof will be omitted.

A display device includes a display panel, a digitizer including non-folding portions and a folding portion, a center bar overlapping the folding portion and wing plates at opposite sides of the center bar. A gap is defined between the center bar and each of the wing plates.

The folding portion includes a first area including first holes and a second area overlapping the gap. Holes (e.g., through-holes) may not be disposed in the second area or a size of second holes disposed in the second area may be less than the size of the first holes. A maximum elongation distance/rate of the second area is less than that of the first area to prevent the digitizer from being damaged by being caught or pinched between the center bar and the wing plate when the display device is folded/unfolded. Therefore, the impact resistance of the folding portion may be increased and the reliability of a circuit interconnect disposed in the folding portion may be increased.

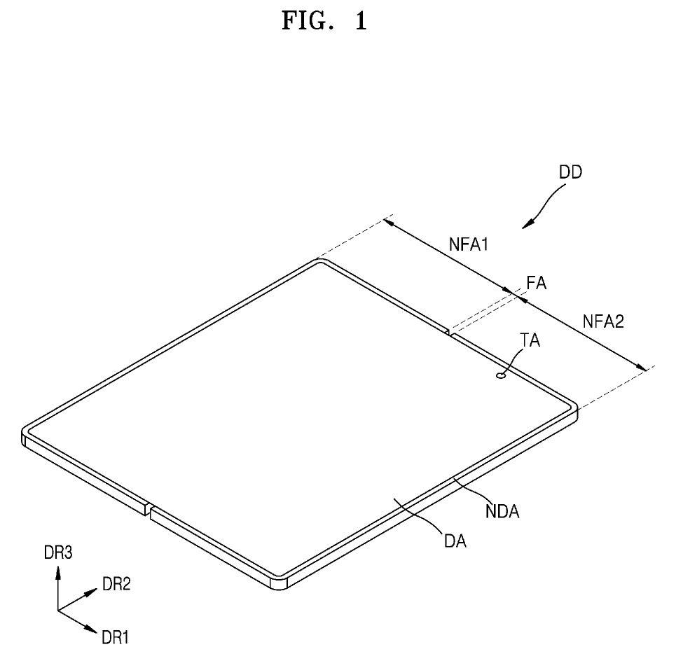

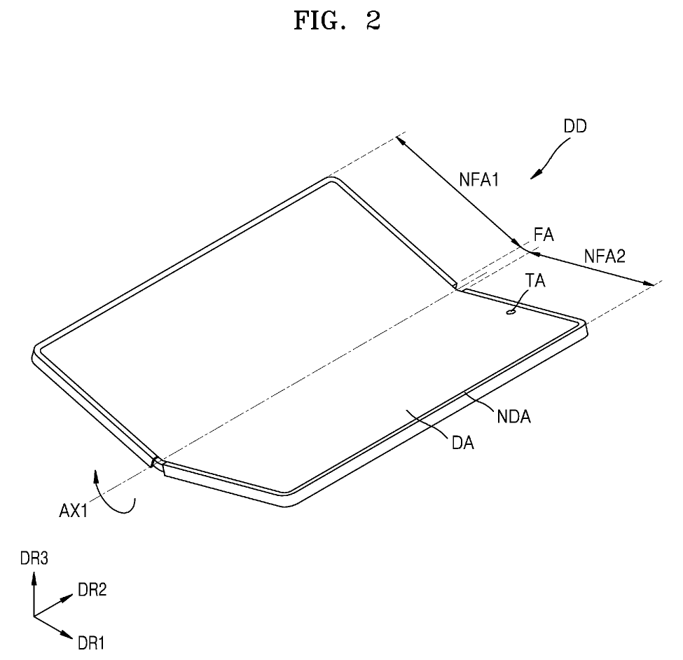

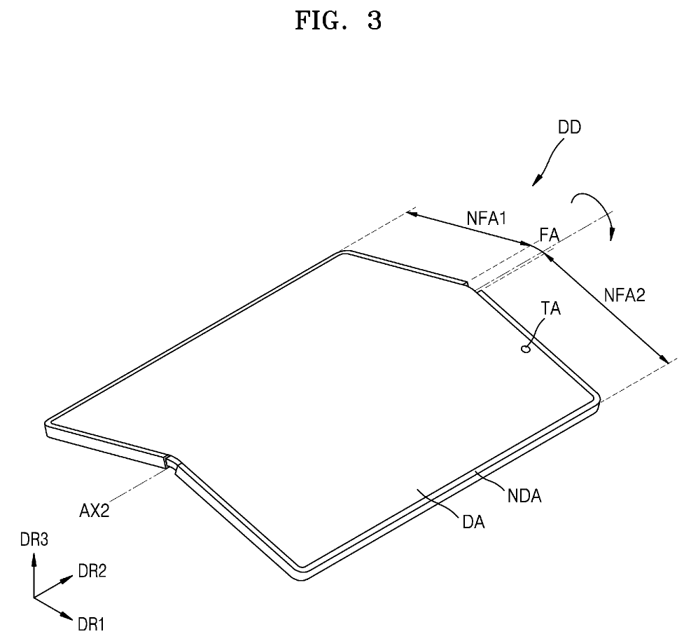

FIG. 1 is a perspective view illustrating an unfolded shape of a display device DD according to an embodiment of the present disclosure. FIGS. 2 and 3 are perspective views illustrating a folded shape of the display device DD of FIG. 1. For example, FIG. 2 is a perspective view illustrating an in-folded shape of the display device DD of FIGS. 1 and 3 is a perspective view illustrating an out-folded shape of the display device DD of FIG. 1.

In the present specification, a plane may be defined in a first direction DR1 and a second direction DR2 intersecting the first direction DR1. For example, in an embodiment the first direction DR1 and the second direction DR2 may be perpendicular to each other. A normal direction of the plane, that is, a thickness direction of the display device DD, may be a third direction DR3. For example, the third direction DR3 may be perpendicular to each of the first direction DR1 and the second direction DR2. However, embodiments of the present disclosure are not necessarily limited thereto and the first to third directions DR1 to DR3 may intersect (e.g., cross) each other at various different angles.

Referring to FIGS. 1, 2 and 3, the display device DD may include a display area DA, a transmissive area TA, and a non-display area NDA.

The display area DA may be an area that generates light and displays an image. A plurality of pixels may be disposed in the display area DA. For example, the pixels may be disposed in a matrix form in the first direction DR1 and the second direction DR2 intersecting the first direction DR1. For example, the first direction DR1 and the second direction DR2 may be perpendicular to each other. Each of the pixels may generate light according to a driving signal. Accordingly, an image may be displayed in the display area DA. For example, in the display area DA, an image may be displayed in the third direction DR3 intersecting each of the first direction DR1 and the second direction DR2. For example, the third direction DR3 may be perpendicular to each of the first direction DR1 and the second direction DR2.

The non-display area NDA may be an area that does not display an image. The non-display area NDA may be positioned around the display area DA (e.g., in a plan view). The non-display area NDA may surround at least a portion of the display area DA in a plan view. However, embodiments of the present disclosure are not necessarily limited thereto, and an image may be displayed in at least a portion of the non-display area NDA. For example, light-generating pixels may be disposed in at least a portion of the non-display area NDA.

The transmissive area TA may have higher transmissivity than the display area DA and the non-display area NDA. In an embodiment, the display device DD may capture an external image by using visible light passing through the transmissive area TA and may further include a sensor that determines the approach of an external object by using infrared light. The sensor may overlap the transmissive area TA in a plan view. For example, the transmissive area TA may be positioned in the display area DA. However, embodiments of the present disclosure are not necessarily limited thereto, and the transmissive area TA may be positioned in the non-display area NDA or may be surrounded by the display area DA and the non-display area NDA in a plan view in some embodiments.

As shown in FIG. 2, the display device DD may be a foldable display device. For example, the display device DD may be folded along a virtual first folding axis AX1 extending in the second direction DR2.

The display device DD may include a folding area FA and non-folding areas NFA1 and NFA2. The folding area FA may be an area in which the display device DD is bent or folded (e.g., is foldable or otherwise deformable). The folding area FA may be bent or folded about the first folding axis AX1. The non-folding areas NFA1 and NFA2 may be areas in which the display device DD is not bent or folded (e.g., is not foldable). In an embodiment, the non-folding areas NFA1 and NFA2 may include a first non-folding area NFA1 and a second non-folding area NFA2 that are spaced apart from each other (e.g., in the first direction DR1). The folding area FA may be positioned between the first non-folding area NFA1 and the second non-folding area NFA2. For example, in an embodiment the first non-folding area NFA1 may be adjacent to the folding area FA in a direction opposite to the first direction DR1, and the second non-folding area NFA2 may be adjacent to the folding area FA in the first direction DR1.

The display device DD may be folded along the first folding axis AX1 in an in-folding manner. Here, the in-folding manner may refer to a manner in which the display area DA is disposed and folded inward.

However, embodiments of the present disclosure are not necessarily limited thereto, and as shown in FIG. 3, the display device DD may be folded along a virtual second folding axis AX2 extending in the second direction DR2. In this case, the display device DD may be folded along the second folding axis AX2 in an out-folding manner. Here, the out-folding manner may refer to a manner in which the display area DA is disposed and folded outward.

For example, in an embodiment the display device DD may be operated about one folding axis in the in-folding manner or the out-folding manner.

In FIGS. 1 to 3, the display device DD is illustrated as including one folding area FA, but embodiments of the present disclosure are not necessarily limited thereto. For example, the display device DD may be folded a plurality of times or may have a plurality of folding areas to implement a rollable display device.

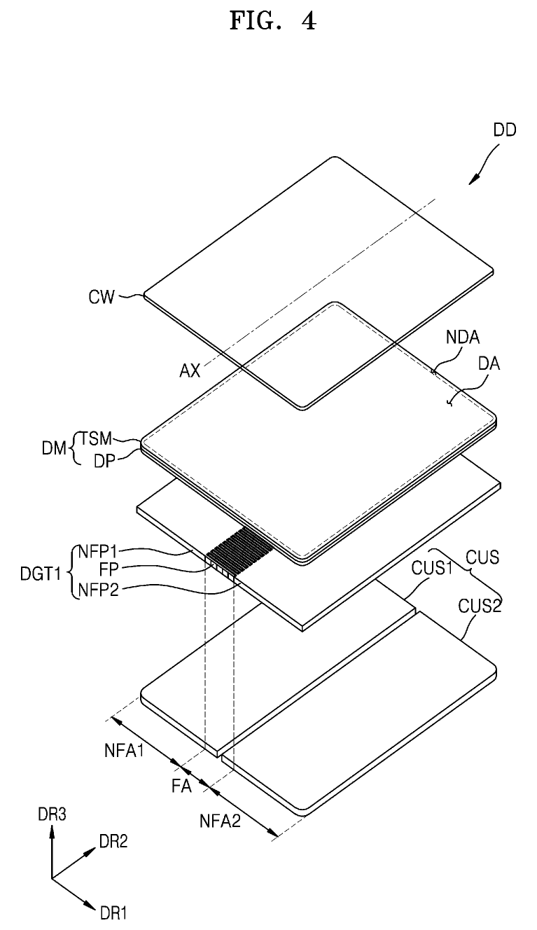

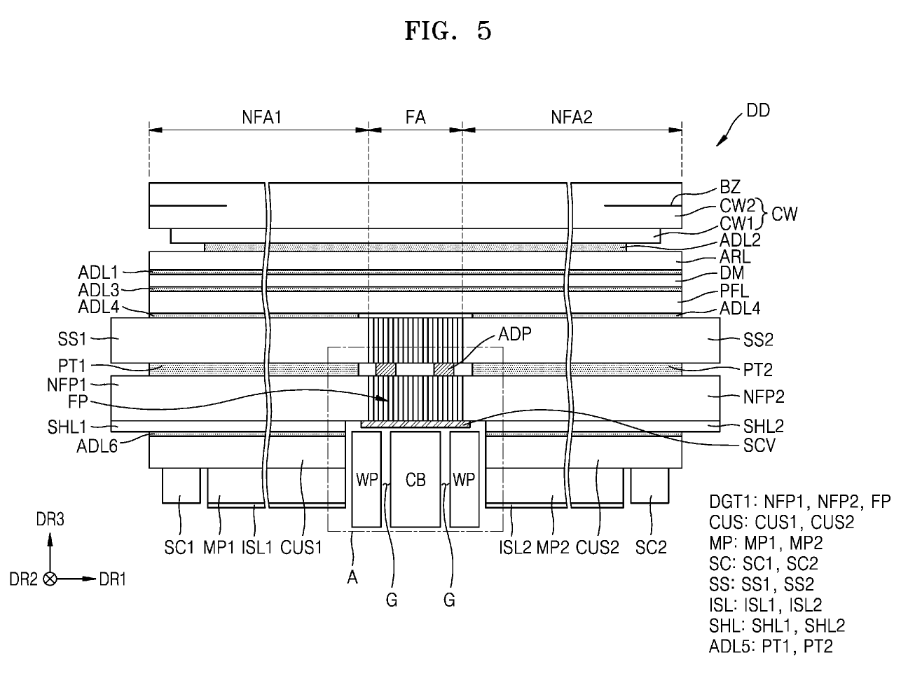

FIG. 4 is an exploded perspective view illustrating the display device DD of FIG. 1. FIG. 5 is a cross-sectional view illustrating the display device DD of FIG. 1.

Referring to FIGS. 4 and 5, in an embodiment the display device DD may include a display module DM, upper functional layers disposed on the display module DM (e.g., in the third direction DR3), and lower functional layers disposed below the display module DM (e.g., in a direction opposite to the third direction DR3). For example, in an embodiment the upper functional layers may include an anti-reflective layer ARL and a cover window CW. For example, in an embodiment the lower functional layers may include a protective layer PFL, a digitizer DGT1, a shielding layer SHL, a cushion layer CUS, a metal plate MP, a step compensation member SC, and an lower insulating layer ISL.

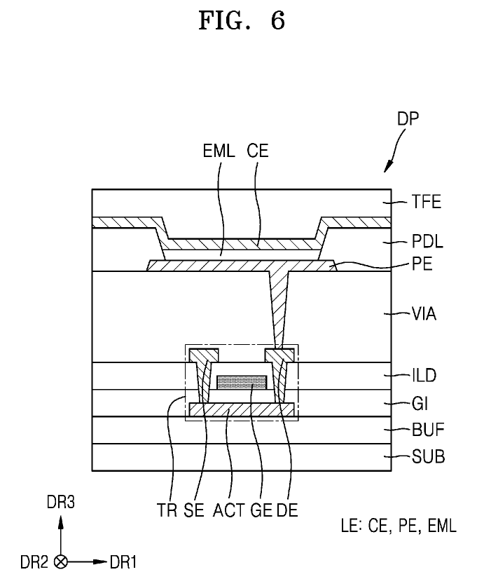

In an embodiment, the display module DM may include a display panel DP and a touch member TSM. The display panel DP may include the pixels that generate and emit light. A cross-sectional structure of the display panel DP will be described in more detail below with reference to FIG. 6.

The touch member TSM may be disposed on the display panel DP (e.g., in the third direction DR3). For example, in an embodiment the touch member TSM may be disposed directly on the display panel DP without a separate adhesive member therebetween. As another example, the touch member TSM may be attached to an upper surface of the display panel DP through an adhesive member.

The touch member TSM may detect a touch of a user. For example, the touch member TSM may acquire coordinate information according to an external input such as a touch of a user. For example, in an embodiment the touch member TSM may acquire coordinate information according to an external input by using a mutual capacitance method and/or a self-capacitance method. The touch member TSM may include a plurality of touch electrodes, second connection interconnects connected to corresponding touch electrodes, and at least one touch insulating layer.

The anti-reflective layer ARL may be disposed on the touch member TSM (e.g., in the third direction DR3). The anti-reflective layer ARL may be attached to an upper surface of the display module DM through a first adhesive layer ADL1. In some embodiments, the anti-reflective layer ARL may be attached to an upper surface of the touch member TSM through the first adhesive layer ADL1. The anti-reflective layer ARL may reduce external light from being reflected from the display device DD. For example, in an embodiment the anti-reflective layer ARL may include a polarizer and/or a phase retarder. For example, the anti-reflective layer ARL may include color filters and a black matrix disposed between the color filters.

The first adhesive layer ADL1 may be disposed between the display module DM and the anti-reflective layer ARL (e.g., in the third direction DR3). The first adhesive layer ADL1 may attach the display module DM to the anti-reflective layer ARL.

The cover window CW may be disposed on the anti-reflective layer ARL (e.g., in the third direction DR3). The cover window CW may include a transparent material to externally transmit light provided from the display module DM. In an embodiment, the cover window CW may include a flexible material. Accordingly, the cover window CW may be folded about a folding axis AX. In an embodiment, the cover window CW may include a first cover layer CW1, a second cover layer CW2, and a bezel pattern BZ.

The first cover layer CW1 may be disposed on the anti-reflective layer ARL (e.g., in the third direction DR3). In an embodiment, the first cover layer CW1 may be attached to an upper surface of the anti-reflective layer ARL through a second adhesive layer ADL2. The first cover layer CW1 may include thin film glass or a synthetic resin. For example, in an embodiment the synthetic resin may include polyimide or polyethylene terephthalate (PET).

The second adhesive layer ADL2 may be disposed between the anti-reflective layer ARL and the first cover layer CW1 (e.g., in the third direction DR3). The second adhesive layer ADL2 may attach the anti-reflective layer ARL to the first cover layer CW1.

The second cover layer CW2 may be disposed on the first cover layer CW1 (e.g., in the third direction DR3). The second cover layer CW2 may include a material having a relatively lower modulus than the first cover layer CW1. In addition, the second cover layer CW2 may have a thickness (e.g., a length in the third direction DR3) that is relatively greater than a thickness of the first cover layer CW1. Accordingly, the second cover layer CW2 may protect the first cover layer CW1. For example, the second cover layer CW2 may have a multilayer structure. For example, the second cover layer CW2 may include an anti-fingerprint layer.

The bezel pattern BZ may be disposed inside the second cover layer CW2. The bezel pattern BZ may be disposed at an edge of the second cover layer CW2. In an embodiment, the bezel pattern BZ may include a light-blocking material capable of blocking light. For example, the bezel pattern BZ may include an organic material, an inorganic material, or the like that includes a light-blocking material having a black color.

The protective layer PFL may be disposed below the display module DM (e.g., in a direction opposite to the third direction DR3). In an embodiment, the protective layer PFL may be attached to a lower surface of the display module DM through a third adhesive layer ADL3. The protective layer PFL may protect the display module DM from an external impact. The protective layer PFL may include an organic material having flexibility. For example, in an embodiment the protective layer PFL may include polyimide, PET, polyethylene naphthalate (PEN), or the like.

The third adhesive layer ADL3 may be disposed between the display module DM and the protective layer PFL (e.g., in the third direction DR3). The third adhesive layer ADL3 may attach the display module DM to the protective layer PFL.

A panel support SS may be disposed between the display panel DP and the digitizer DGT1 (e.g., in the third direction DR3 which is a thickness direction of the display module DM). The panel support SS may be disposed below the protective layer PFL and may serve to support the lower surface of the display module DM. The panel support SS may be a rigid member of which a shape or volume is not easily changed by external pressure. In an embodiment, a thickness (e.g., length in the third direction DR3) of the panel support SS may be, for example, in a range of about 30 μm to about 200 μm.

In an embodiment, the panel support SS may include a first panel support SS1 overlapping the first non-folding area NFA1 in the third direction DR3, a second panel support SS2 overlapping the second non-folding area NFA2 in the third direction DR3, and a lattice pattern overlapping the folding area FA in the third direction DR3 to be easily bent in the folding area FA.

In an embodiment, the panel support SS may be attached to a lower surface of the protective layer PFL through a fourth adhesive layer ADL4.

The fourth adhesive layer ADL4 may be disposed between the protective layer PFL and the panel support SS (e.g., in the third direction DR3). In some embodiments, the fourth adhesive layer ADL4 may include a first portion and a second portion. The first portion of the fourth adhesive layer ADL4 may be spaced apart from the second portion of the fourth adhesive layer ADL4 in the first direction DR1 with the folding area FA interposed between the first portion and the second portion. The first portion of the fourth adhesive layer ADL4 may attach a portion of the protective layer PFL to the first panel support SS1. The second portion of the fourth adhesive layer ADL4 may attach another portion of the protective layer PFL to the second panel support SS2.

The digitizer DGT1 may be disposed on a side surface of the display panel DP. For example, in an embodiment a first surface (e.g., an upper surface) of the digitizer DGT1 may be disposed on a side surface (e.g., a lower side surface) of the display module DM. In some embodiments, the digitizer DGT1 may be disposed on a lower portion of the panel support SS. In an embodiment, the digitizer DGT1 may be attached to a lower surface of the panel support SS through a fifth adhesive layer ADL5. In an embodiment, the digitizer DGT1 may detect an input through an electromagnetic pen. For example, the digitizer DGT1 may be driven by using electromagnetic resonance (EMR).

In an embodiment, the digitizer DGT1 may include a first non-folding portion NFP1, a second non-folding portion NFP2, and a folding portion FP. The first and second non-folding portions NFP1 and NFP2 may be portions of the digitizer DGT1 that are not bent or folded (e.g., are not foldable), and the folding portion FP may be a portion of the digitizer DGT1 that is bent or folded (e.g., is foldable).

The first non-folding portion NFP1 may at least partially overlap the first non-folding area NFA1 in a plan view. The second non-folding portion NFP2 may at least partially overlap the second non-folding area NFA2 in a plan view. The folding portion FP may at least partially overlap the folding area FA in a plan view. The folding portion FP may be positioned between the first non-folding portion NFP1 and the second non-folding portion NFP2 (e.g., in the first direction DR1). For example, the first non-folding portion NFP1 may be adjacent to the folding portion FP in the direction opposite to the first direction DR1, and the second non-folding portion NFP2 may be adjacent to the folding portion FP in the first direction DR1.

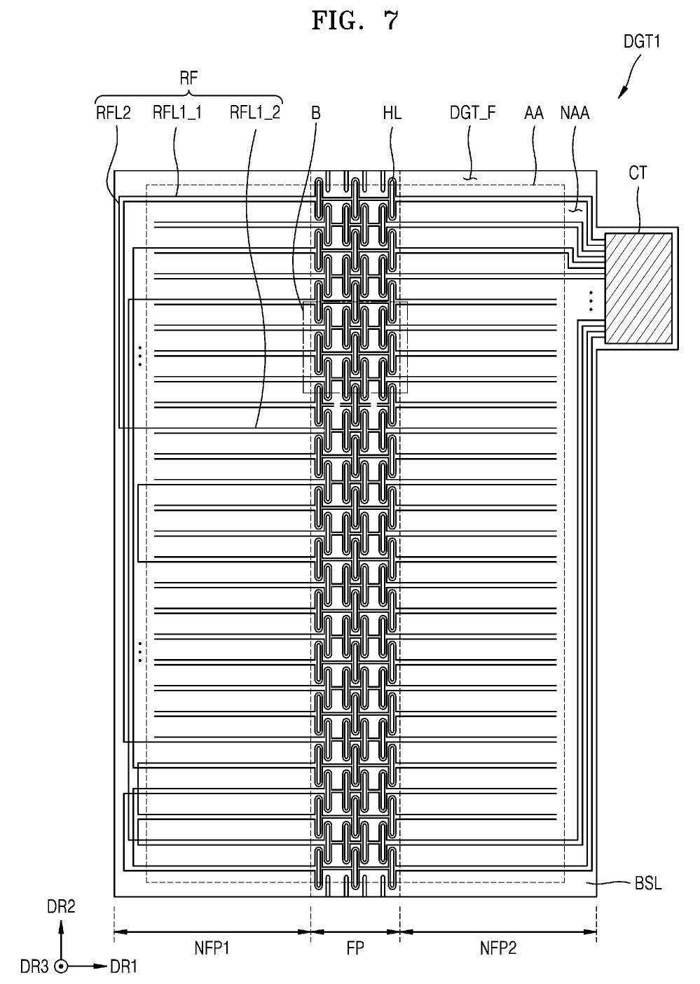

A plurality of through-holes HL (FIG. 7) may be defined in the folding portion FP. The through-holes HL may pass through the folding portion FP in a thickness direction (e.g., the third direction DR3). The through-holes HL may be spaced apart from each other in the first direction DR1. In addition, the through-holes HL may be spaced apart from each other in the second direction DR2.

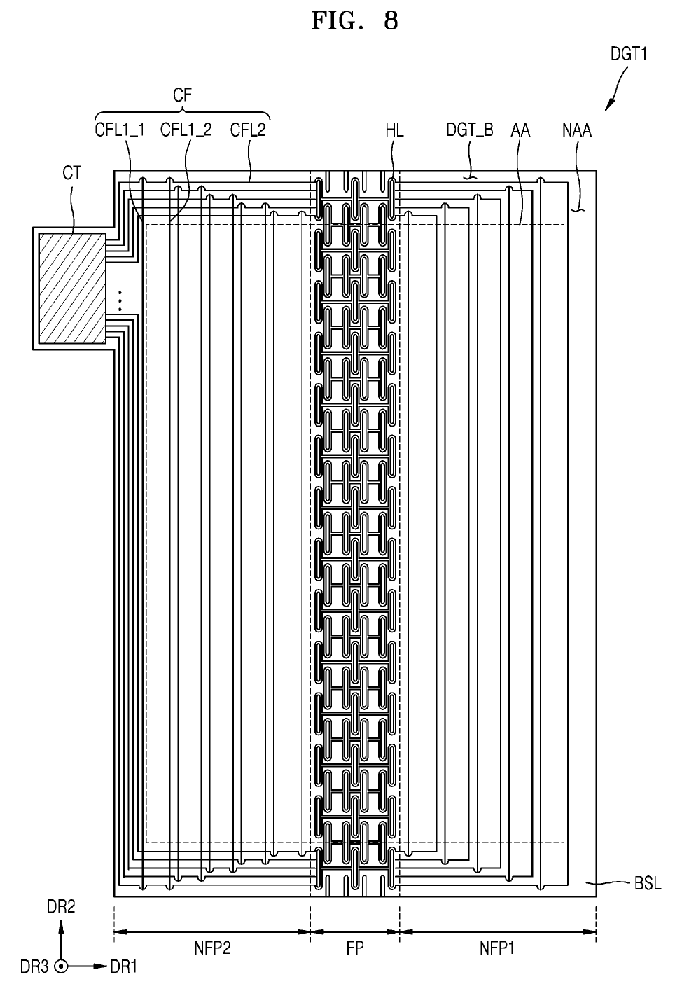

In an embodiment, the digitizer DGT1 may further include sensing coils (e.g., first sensing coils RF of FIG. 7 or second sensing coils CF of FIG. 8) that are curved and extend along at least portions of edges of the through-holes HL in a plan view. A base layer on which the sensing coils are disposed (e.g., a base layer BSL of FIG. 7) may include a material having a relatively low permittivity. For example, in an embodiment the base layer may be a polyimide film, but embodiments of the present disclosure are not necessarily limited thereto. For example, in an embodiment a thickness of the digitizer DGT1 (e.g., a length in the third direction DR3) may be less than or equal to about 400 micrometers (μm).

The digitizer DGT1 may include the folding portion FP corresponding to the folding area FA and thus may secure flexibility during a folding operation of the display device DD so that a shape of the digitizer DGT1 may be easily changed and may be easily folded.

The fifth adhesive layer ADL5 may be disposed between the panel support SS and the digitizer DGT1 (e.g., in the third direction DR3). In some embodiments, the fifth adhesive layer ADL5 may include a first portion PT1 that attaches the first panel support SS1 to the first non-folding portion NFP1 and a second portion PT2 that attaches the second panel support SS2 to the second non-folding portion NFP2.

As an example, the first portion PT1 of the fifth adhesive layer ADL5 may be spaced apart from the second portion PT2 of the fifth adhesive layer ADL5 in the first direction DR1 with the folding area FA interposed between the first portion PT1 and the second portion PT2. The fifth adhesive layer ADL5 may not overlap the folding portion FP of the digitizer DGT1 in the third direction DR3.

In an unfolded state of the display device DD, a gap G which is a separation space may be defined between a center bar CB and each of wing plates WP. As an example, on the same layer as the fifth adhesive layer ADL5, an adhesive portion ADP may be additionally disposed in one area of the folding portion FP that overlaps the gap G in the third direction DR3. Due to the adhesive portion ADP, interference problems occurring between the center bar CB and the wing plates WP may be alleviated and prevented.

A cover layer SCV may be disposed on the other surface (hereinafter referred to as “lower surface”) of the digitizer DGT1 in a direction opposite to the third direction DR3. In some embodiments, the cover layer SCV may be disposed on an area of the lower surface of the digitizer DGT1 which overlaps the folding area FA in the third direction DR3. The cover layer SCV may include an elastic material of which a length is variable according to folding and unfolding operations of the display device DD.

In an embodiment, the cover layer SCV may include a polymer material having hyper elastic properties. For example, the cover layer SCV may include an elastic thermoplastic polyurethane (TPU). In an embodiment, the cover layer SCV may have a thickness (e.g., length in the third direction DR3) in a range of about 1 μm to about 20 μm.

In some embodiments, the cover layer SCV may have a low modulus to correspond to folding and unfolding operations of the display device DD. For example, in an embodiment the cover layer SCV may include a material having a modulus of less than or equal to about 1 GPa.

The cover layer SCV may prevent external foreign materials from entering the digitizer DGT1.

The shielding layer SHL may be disposed below the digitizer DGT1 (e.g., in a direction opposite to the third direction DR3). For example, in an embodiment the shielding layer SHL may be disposed on the lower surface of the digitizer DGT1 without a separate adhesive member. As another example, the shielding layer SHL may be attached to the lower surface of the digitizer DGT1 through an adhesive member. The shielding layer SHL may block electromagnetic interference noise. The shielding layer SHL may include a metal. For example, in an embodiment the shielding layer SHL may include a magnetic metal powder (MMP). However, embodiments of the present disclosure are not necessarily limited thereto, and in some embodiments the shielding layer SHL may include permalloy, invar, stainless steel, or the like which is an alloy of nickel (Ni) and iron (Fe).

In an embodiment, the shielding layer SHL may include a first shielding layer SHL1 and a second shielding layer SHL2. The first shielding layer SHL1 may be spaced apart from the second shielding layer SHL2 in the first direction DR1 in the folding area FA. The first shielding layer SHL1 may overlap a portion of the folding portion FP and the first non-folding portion NFP1 in a plan view. The second shielding layer SHL2 may overlap another portion of the folding portion FP and the second non-folding portion NFP2 in a plan view. However, embodiments of the present disclosure are not necessarily limited thereto. For example, in some embodiments the cover layer SCV may not be present, and the shielding layer SHL may overlap an entirety of the folding area FA in a plan view and may cover the through-holes HL. In some embodiments, the shielding layer SHL may not overlap the folding portion FP and may only overlap the first and second non-folding portions NFP1, NFP2 in a plan view.

The cushion layer CUS may be disposed below the shielding layer SHL (e.g., in a direction opposite to the third direction DR3). In an embodiment, the cushion layer CUS may be attached to a lower surface of the shielding layer SHL through a sixth adhesive layer ADL6. The cushion layer CUS may protect the display module DM and the digitizer DGT1 from an external impact. In addition, the cushion layer CUS may prevent foreign materials from entering the through-holes HL when the display device DD is spread (e.g., is unfolded). For example, in an embodiment the cushion layer CUS may include rubber, a urethane-based material, an acrylic-based material, foam tape, a foam pad, or the like.

In an embodiment, the cushion layer CUS may include a first cushion layer CUS1 and a second cushion layer CUS2. The first cushion layer CUS1 may be spaced apart from the second cushion layer CUS2 in the first direction DR1 in the folding area FA. The first cushion layer CUS1 may overlap the first shielding layer SHL1 in a plan view. In addition, the first cushion layer CUS1 may overlap a portion of the folding portion FP and the first non-folding portion NFP1 in a plan view. The second cushion layer CUS2 may overlap the second shielding layer SHL2 in a plan view. In addition, the second cushion layer CUS2 may overlap another portion of the folding portion FP and the second non-folding portion NFP2 in a plan view. In some embodiments, the cushion layer CUS may not overlap the folding portion FP and may only overlap the first and second non-folding portions NFP1, NFP2 in a plan view.

The first cushion layer CUS1 may be spaced apart from the second cushion layer CUS2 in the first direction DR1 in the folding area FA, and thus when the folding portion FP is folded with curvature, a shape of the digitizer DGT1 may be easily transformed.

The sixth adhesive layer ADL6 may be disposed between the shielding layer SHL and the cushion layer CUS (e.g., in a third direction DR3). In some embodiments, the sixth adhesive layer ADL6 may include a first portion and a second portion. The first portion of the sixth adhesive layer ADL6 may be spaced apart from the second portion of the sixth adhesive layer ADL6 in the first direction DR1 in the folding area FA. The first portion of the sixth adhesive layer ADL6 may attach the first shielding layer SHL1 to the first cushion layer CUS1. The second portion of the sixth adhesive layer ADL6 may attach the second shielding layer SHL2 to the second cushion layer CUS2.

In an embodiment, the metal plate MP, the step compensation member SC, and the lower insulating layer ISL may be disposed below the cushion layer CUS (e.g., in a direction opposite to the third direction DR3).

The metal plate MP may protect the display module DM from an external impact. For example, in an embodiment the metal plate MP may include stainless steel, but embodiments of the present disclosure are not necessarily limited thereto. In an embodiment, the metal plate MP may include a first metal layer MP1 and a second metal layer MP2. The first metal layer MP1 may be in direct contact with the first cushion layer CUS1, and the second metal layer MP2 may be in direct contact with the second cushion layer CUS2.

In an embodiment, the step compensation member SC may include double-sided tape or an insulating film. In an embodiment, the step compensation member SC may include a first step compensation layer SC1 and a second step compensation layer SC2. The first step compensation layer SC1 may be in direct contact with the first cushion layer CUS1 and may be adjacent to the first metal layer MP1. The second step compensation layer SC2 may be in direct contact with the second cushion layer CUS2 and may be adjacent to the second metal layer MP2.

The lower insulating layer ISL may be disposed below the metal plate MP (e.g., in a direction opposite to the third direction DR3). The lower insulating layer ISL may block noise such as static electricity generated from the outside (e.g., the external environment). The lower insulating layer ISL may include an inorganic insulating material and/or an organic insulating material. In an embodiment, the lower insulating layer ISL may include a first lower insulating layer ISL1 and a second lower insulating layer ISL2. The first lower insulating layer ISL1 may be in direct contact with the first metal layer MP1, and the second lower insulating layer ISL2 may be in direct contact with the second metal layer MP2.

The display device DD may include the center bar CB that is positioned opposite to the display panel DP (e.g., in a direction opposite to the third direction DR3) with respect to the digitizer DGT1 and overlaps the folding portion FP (e.g., in a direction opposite to the third direction DR3), and the wing plates WP respectively positioned at opposite sides of the center bar CB in the first direction DR1. For example, in an embodiment, the center bar CB may be disposed on a second side (e.g., a lower side surface) of the digitizer DGT1 opposite to the first side surface of the digitizer DGT1.

In an embodiment, the display device DD may include a folding set disposed below the digitizer DGT1, and the folding set may accommodate the display module DM and the digitizer DGT1 and may fold the display module DM. The folding set may include the center bar CB and the wing plates WP.

In an embodiment, the folding set may include a first set overlapping the first non-folding area NFA1 in the third direction DR3 and a second set overlapping the second non-folding area NFA2. A hinge may be disposed between the first set and the second set to fold the display device DD.

The wing plate WP may be disposed between the first set and the hinge and between the second set and the hinge. The wing plates WP may maintain a shape in which the display device DD is folded to fold the digitizer DGT1. The wing plates WP may serve to alleviate the bending stress of the display module DM when the display device DD is folded. In an embodiment, the wing plates WP may rotate about a rotation axis extending in the second direction DR2.

The center bar CB may be positioned between the wing plates WP (e.g., in the first direction DR1) and may be defined as an area protruding from the hinge towards the digitizer DGT1 in the third direction DR3. The center bar CB may prevent the folding portion FP from sagging when the display device DD is folded and may support the folding portion FP. As an example, when the display device DD is folded, a partial area of the center bar CB may come into direct contact with the folding portion FP.

The center bar CB may be applied to the display device DD including the digitizer DGT1 in which the first non-folding area NFA1, the folding area FA, and the second non-folding area NFA2 are integrally connected to each other, thereby reducing a thickness of the display device DD.

FIG. 6 is a cross-sectional view illustrating the display panel DP included in the display device DD of FIG. 1.

Referring to FIG. 6, in an embodiment the display panel DP may include a substrate SUB, a buffer layer BUF, a gate insulating layer GI, an interlayer insulating layer ILD, a via insulating layer VIA, an active layer ACT, a source electrode SE, a gate electrode GE, a drain electrode DE, a pixel electrode PE, a pixel defining layer PDL, an emission layer EML, a common electrode CE, and an encapsulation layer TFE.

In an embodiment, a transistor TR may include the active layer ACT, the source electrode SE, the gate electrode GE, and the drain electrode DE. A light-emitting element LE may include the common electrode CE, the pixel electrode PE, and the emission layer EML.

The substrate SUB may constitute a base of the display device DD. The substrate SUB may include a transparent material or an opaque material. For example, in an embodiment the substrate SUB may include glass, quartz, plastic, silicon, or the like. The materials may be used alone or in combination with each other.

The buffer layer BUF may be disposed on the substrate SUB (e.g., disposed directly thereon in the third direction DR3). The buffer layer BUF may prevent metal atoms or impurities from diffusing from the substrate SUB to the transistor TR. In addition, the buffer layer BUF may increase the flatness of a surface of the substrate SUB when the surface of the substrate SUB is not uniform. For example, in an embodiment the buffer layer BUF may include an inorganic insulating material such as silicon oxide (SiOₓ), silicon nitride (SiNₓ), or silicon oxynitride (SiOₓN_{y}). The materials may be used alone or in combination with each other.

The active layer ACT may be disposed on the buffer layer BUF (e.g., disposed directly thereon in the third direction DR3). The active layer ACT may include a source region, a drain region, and a channel region positioned between the source region and the drain region. The source region and the drain region may have higher conductivity than the channel region. The active layer ACT may include an oxide semiconductor, a silicon semiconductor, or the like. For example, in an embodiment the oxide semiconductor may include at least one oxide selected from indium (In), gallium (Ga), tin (Sn), zirconium (Zr), vanadium (V), hafnium (Hf), cadmium (Cd), germanium (Ge), chromium (Cr), titanium (Ti), or zinc (Zn). The silicon semiconductor may include amorphous silicon, polycrystalline silicon, or the like.

The gate insulating layer GI may be disposed on the buffer layer BUF (e.g., disposed directly thereon) and may cover at least a portion of the active layer ACT. For example, in an embodiment the gate insulating layer GI may include an inorganic insulating material such as silicon oxide, silicon nitride, or silicon oxynitride. The materials may be used alone or in combination with each other.

The gate electrode GE may be disposed on the gate insulating layer GI (e.g., disposed directly thereon in the third direction DR3). The gate electrode GE may overlap the channel region of the active layer ACT in a plan view. For example, the gate electrode GE may include a conductive material such as a metal, an alloy, a conductive metal nitride, a conductive metal oxide, or a transparent conductive material. For example, in an embodiment the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium SC, neodymium (Nd), iridium (Ir), an alloy containing aluminum, an alloy containing silver, an alloy containing copper, an alloy containing molybdenum, aluminum nitride (AlNₓ), tungsten nitride (WNₓ), titanium nitride (TiNₓ), chromium nitride (CrNₓ), tantalum nitride (TaNₓ), zinc oxide (ZnOₓ), indium tin oxide (ITO), tin oxide (SnOₓ), indium oxide (InOₓ), gallium oxide (GaOₓ), indium zinc oxide (IZO), or the like. The materials may be used alone or in combination with each other.

The interlayer insulating layer ILD may be disposed on (e.g., disposed directly thereon) the gate insulating layer GI and may cover the gate electrode GE. For example, in an embodiment the interlayer insulating layer ILD may include an inorganic insulating material such as silicon oxide, silicon nitride, or silicon oxynitride. The materials may be used alone or in combination with each other.

The source electrode SE and the drain electrode DE may be disposed on the interlayer insulating layer ILD. In an embodiment, the source electrode SE may be connected to the source region of the active layer ACT through a first contact hole passing through lower insulating layers (for example, the gate insulating layer GI and the interlayer insulating layer ILD). The drain electrode DE may be connected to the drain region of the active layer ACT through a second contact hole passing through the lower insulating layers (for example, the gate insulating layer GI and the interlayer insulating layer ILD). For example, in an embodiment the source electrode SE and the drain electrode DE may include a conductive material such as a metal, an alloy, a conductive metal nitride, a conductive metal oxide, or a transparent conductive material. The materials may be used alone or in combination with each other.

The via insulating layer VIA may be disposed on (e.g., disposed directly thereon) the interlayer insulating layer ILD and may cover the source electrode SE and the drain electrode DE. For example, in an embodiment the via insulating layer VIA may include an organic insulating material such as a photoresist, an acrylic resin, a polyimide resin, a polyamide resin, a siloxane resin, or an epoxy resin. The materials may be used alone or in combination with each other.

The pixel electrode PE may be disposed on the via insulating layer VIA (e.g., disposed directly thereon in the third direction DR3). In an embodiment, the pixel electrode PE may be electrically connected to the transistor TR. For example, the pixel electrode PE may be connected to the drain electrode DE (or the source electrode SE) through a contact hole passing through a lower insulating layer (for example, the via insulating layer VIA). For example, the pixel electrode PE may be a first terminal (for example, an anode) of the light-emitting element LE. For example, in an embodiment the pixel electrode PE may include a conductive material such as a metal, an alloy, a conductive metal nitride, a conductive metal oxide, or a transparent conductive material. The materials may be used alone or in combination with each other.

The pixel defining layer PDL may be disposed on (e.g., disposed directly thereon) the pixel electrode PE and may cover at least a portion of the pixel electrode PE. The pixel defining layer PDL may define an opening that exposes at least a portion of the pixel electrode PE. For example, in an embodiment, the pixel defining layer PDL may cover lateral ends of the pixel electrode PE and expose a central portion of the pixel electrode PE. For example, in an embodiment the pixel defining layer PDL may include an organic insulating material such as a photoresist, an acrylic resin, a polyimide resin, or a polyamide resin, and/or an inorganic insulating material such as silicon oxide, silicon nitride, or silicon oxynitride. The materials may be used alone or in combination with each other.

The emission layer EML may be disposed on the pixel electrode PE (e.g., in the third direction DR3). The emission layer EML may be positioned in the opening of the pixel defining layer PDL. The emission layer EML may include a light-emitting material. For example, in an embodiment the emission layer EML may include at least one selected from an organic light-emitting material or quantum dots. The emission layer EML may further include a functional layer including at least one of a hole injection layer, a hole transport layer, an electron transport layer, or an electron injection layer.

The common electrode CE may be disposed on the emission layer EML (e.g., in the third direction DR3). For example, the common electrode CE may be a second terminal (for example, a cathode) of the light-emitting element LE. For example, in an embodiment the common electrode CE may include a conductive material such as a metal, an alloy, a conductive metal nitride, a conductive metal oxide, or a transparent conductive material. The materials may be used alone or in combination with each other.

The encapsulation layer TFE may be disposed on (e.g., disposed directly thereon) the common electrode CE. The encapsulation layer TFE may prevent impurities such as oxygen and moisture from penetrating into the light-emitting element LE. The encapsulation layer TFE may include at least one inorganic layer and at least one organic layer.

FIGS. 7 and 8 are plan views illustrating the digitizer DGT1 according to an embodiment of the present disclosure.

For example, FIG. 7 is a plan view illustrating a front surface DGT_F of the digitizer DGT1 of FIGS. 4, 5, and 8, is a plan view illustrating a rear surface DGT_B of the digitizer DGT1 of FIGS. 4 and 5. For example, FIG. 7 illustrates the sensing coils disposed on the front surface DGT_F of the digitizer DGT1, and FIG. 8 illustrates the sensing coils disposed on the rear surface DGT_B of the digitizer DGT1.

Referring to FIGS. 7 and 8, the digitizer DGT1 may include an active area AA and a non-active area NAA.

The active area AA of the digitizer DGT1 may overlap a display area (for example, the display area DA of FIG. 1) of a display device (for example, the display device DD of FIG. 1) in a plan view. For example, the active area AA of the digitizer DGT1 may correspond to the display area of the display device. However, embodiments of the present disclosure are not necessarily limited thereto, and the active area AA of the digitizer DGT1 may at least partially overlap a non-display area (for example, the non-display area NDA of FIG. 1) of the display device in a plan view.

The non-active area NAA of the digitizer DGT1 may overlap the non-display area of the display device in a plan view. For example, the non-active area NAA of the digitizer DGT1 may correspond to the non-display area of the display device. However, embodiments of the present disclosure are not necessarily limited thereto, and the non-active area NAA of the digitizer DGT1 may at least partially overlap the display area of the display device in a plan view.

For example, the active area AA may be defined as an area that detects a pen input. In addition, the non-active area NAA may be an area in which connection interconnects through which each of the first sensing coils RF and the second sensing coils CF constitutes a loop are disposed. In the non-active area NAA, the connection interconnects through which each of the first sensing coils RF and the second sensing coils CF constitutes a loop may be densely disposed.

In an embodiment, the digitizer DGT1 may include the base layer BSL, the first sensing coils RF, the second sensing coils CF, and a connector CT.

The base layer BSL may constitute a base of the digitizer DGT1. In an embodiment, the base layer BSL may include a material having relatively low permittivity. For example, in an embodiment the base layer BSL may include a polyimide film, but embodiments of the present disclosure are not necessarily limited thereto.

The connector CT may be disposed in the non-active area NAA of the digitizer DGT1. For example, the connector CT may be disposed in the first non-folding portion NFP1 or the second non-folding portion NFP2.

In an embodiment, the first sensing coils RF may be disposed on the front surface DGT_F of the digitizer DGT1, and the second sensing coils CF may be disposed on the rear surface DGT_B of the digitizer DGT1. The first and second sensing coils RF and CF may be disposed on the base layer BSL. In an embodiment, the first and second sensing coils RF and CF may include a conductive material such as a metal, an alloy, a conductive metal nitride, a conductive metal oxide, or a transparent conductive material.

In an embodiment, the first sensing coils RF may include first extension interconnects RFL1_1, second extension interconnects RFL1_2, and first connection interconnects RFL2. Each of the first extension interconnects RFL1_1 and the second extension interconnects RFL1_2 may extend in the first direction DR1. For example, each of the first and second extension interconnects RFL1_1 and RFL1_2 may be disposed in the active area AA and the non-active area NAA. Each of the first connection interconnects RFL2 may extend in the second direction DR2. For example, each of the first connection interconnects RFL2 may be disposed in the non-active area NAA. In an embodiment, each of the first connection interconnects RFL2 may connect one end of one of the first extension interconnects RFL1_1 to one end of one of the second extension interconnects RFL1_2. Accordingly, the first sensing coils RF may form a plurality of loops.

In an embodiment, the plurality of loops formed by the first sensing coils RF may include a plurality of loops having different lengths from each other in the second direction DR2. For example, a length of each of the first connection interconnects RFL2, which form the plurality of loops formed by the first sensing coils RF, in the second direction DR2 may be different for each loop. For example, widths between the first extension interconnects RFL1_1 and the second extension interconnects RFL1_2 in the second direction DR2 may be different from each other. However, embodiments of the present disclosure are not necessarily limited thereto, and in an embodiment, the plurality of loops formed by the first sensing coils RF may include a plurality of loops of which lengths in the second direction DR2 are substantially equal to each other. In this case, the lengths of the first connection interconnects RFL2, which form the plurality of loops formed by the first sensing coils RF, in the second direction DR2 may be substantially equal to each other.

Shapes of the plurality of loops formed by the first sensing coils RF may be changed in various ways according to embodiments. For example, the shape of the plurality of loops formed by the first sensing coils RF may be any shape extending in the first direction DR1.

The first and second extension interconnects RFL1_1 and RFL1_2 may be disposed in the first non-folding portion NFP1, the second non-folding portion NFP2, and the folding portion FP. In an embodiment, the first connection interconnects RFL2 may be disposed in the first non-folding portion NFP1 or the second non-folding portion NFP2.

In an embodiment, a portion of each of the first extension interconnects RFL1_1 disposed in the folding portion FP of the digitizer DGT1 may be disposed between the through-holes HL. The portion of each of the first extension interconnects RFL1_1 disposed in the folding portion FP of the digitizer DGT1 may extend continuously from the first non-folding portion NFP1 to the second non-folding portion NFP2 through the through-holes HL. In addition, in an embodiment a portion of each of the second extension interconnects RFL1_2 disposed in the folding portion FP of the digitizer DGT1 may be disposed between the through-holes HL. The portion of each of the second extension interconnects RFL1_2 disposed in the folding portion FP of the digitizer DGT1 may extend continuously from the first non-folding portion NFP1 to the second non-folding portion NFP2 through the through-holes HL.

In an embodiment, each of the first and second extension interconnects RFL1_1 and RFL1_2 may be bent (e.g., have a bent configuration in a plan view) and extend along edges of the through-holes HL in the folding portion FP. Accordingly, each of the first and second extension interconnects RFL1_1 and RFL1_2 may include a curved pattern having curvature (e.g., in a plan view).

Each of the first sensing coils RF may be connected to the connector CT. For example, in an embodiment one end of each of the first sensing coils RF may be connected to the connector CT in the non-active area NAA. For example, the first sensing coils RF may be connected to the connector CT through connector connection interconnects, respectively.

Although FIG. 7 illustrates an example in which the first sensing coils RF are disposed on the front surface DGT_F of the digitizer DGT1, this is for convenience of description, and in some embodiments, some of the first sensing coils RF may be disposed on the rear surface DGT_B of the digitizer DGT1.

The second sensing coils CF may include third extension interconnects CFL1_1, fourth extension interconnects CFL1_2, and second connection interconnects CFL2. Each of the third extension interconnects CFL1_1 and the fourth extension interconnects CFL1_2 may extend in the second direction DR2. For example, the third and fourth extension interconnects CFL1_1 and CFL1_2 may be disposed in the active area AA and the non-active area NAA. Each of the second connection interconnects CFL2 may extend in the first direction DR1. For example, the second connection interconnects CFL2 may be disposed in the non-active area NAA. In an embodiment, each of the second connection interconnects CFL2 may connect one end of one of the third extension interconnects CFL1_1 to one end of one of the fourth extension interconnects CFL1_2. Accordingly, the second sensing coils CF may form a plurality of loops.

In an embodiment, the plurality of loops formed by the second sensing coils CF may include a plurality of loops having different lengths from each other in the first direction DR1. For example, a length of each of the second connection interconnects CFL2, which form the plurality of loops formed by the second sensing coils CF, in the first direction DR1 may be different for each loop. For example, widths between the third extension interconnects CFL1_1 and the fourth extension interconnects CFL1_2 in the first direction DR1 may be different from each other. However, embodiments of the present disclosure are not necessarily limited thereto, and in an embodiment, the plurality of loops formed by the second sensing coils CF may include a plurality of loops of which lengths in the first direction DR1 are substantially equal to each other. In this case, the lengths of the second connection interconnects CFL2, which form the plurality of loops formed by the second sensing coils CF, in the first direction DR1 may be substantially equal to each other.

Shapes of the plurality of loops formed by the second sensing coils CF may be changed in various ways according to embodiments. For example, the shape of the plurality of loops formed by the second sensing coils CF may be any shape extending in the second direction DR2.

In an embodiment, the third and fourth extension interconnects CFL1_1 and CFL1_2 may be disposed in the first non-folding portion NFP1, the second non-folding portion NFP2, and the folding portion FP. The second connection interconnects CFL2 may be disposed in the first non-folding portion NFP1, the second non-folding portion NFP2, and the folding portion FP.

In an embodiment, a portion of each of the third extension interconnects CFL1_1 disposed in the folding portion FP of the digitizer DGT1 may be disposed between the through-holes HL. The portion of each of the third extension interconnects CFL1_1 disposed in the folding portion FP of the digitizer DGT1 may extend in the second direction DR2 through the through-holes HL. In addition, a portion of each of the fourth extension interconnects CFL1_2 disposed in the folding portion FP of the digitizer DGT1 may be disposed between the through-holes HL. The portion of each of the fourth extension interconnects CFL1_2 disposed in the folding portion FP of the digitizer DGT1 may extend in the second direction DR2 through the through-holes HL. In addition, a portion of each of the second connection interconnects CFL2 disposed in the folding portion FP of the digitizer DGT1 may be disposed between the through-holes HL. In an embodiment, the portions of the second connection interconnects CFL2 disposed in the folding portion FP of the digitizer DGT1 may be connected to one ends of the third extension interconnects CFL1_1 and one ends of the fourth extension interconnects CFL1_2 through the through-holes HL.

Each of the second sensing coils CF may be connected to the connector CT. For example, an end of each of the second sensing coils CF may be connected to the connector CT in the non-active area NAA. For example, the second sensing coils CF may be connected to the connector CT through connector connection interconnects, respectively.

Although FIG. 8 illustrates an example in which the second sensing coils CF are disposed on the rear surface DGT_B of the digitizer DGT1, this is for convenience of description, and in some embodiments, some of the second sensing coils CF may be disposed on the front surface DGT_F of the digitizer DGT1.

For example, the first sensing coils RF may be defined as sensing coils, and the second sensing coils CF may be defined as driving coils. When a current flows in the second sensing coils CF, magnetic lines of force may be induced between the second sensing coils CF and the first sensing coils RF. The first sensing coils RF may detect an induced electromagnetic force emitted from an electromagnetic pen and may output a detection signal through one terminal of each of the first sensing coils RF. One terminal of the first sensing coils RF may be connected to signal lines disposed in the non-active area NAA. However, embodiments of the present disclosure are not necessarily limited thereto and the first sensing coils RF may be defined as driving coils, and the second sensing coils CF may be defined as sensing coils in some embodiments.

By applying the center bar CB to the display device DD including the digitizer DGT1 in which the first non-folding area NFA1, the folding area FA, and the second non-folding area NFA2 are integrally connected to each other, the thickness of the display device DD may be reduced, but interference may occur in the digitizer DGT1 between the center bar CB and the wing plate WP.

For example, in some embodiments, the digitizer DGT1 may be damaged due to being caught or pinched between the center bar CB and the wing plate WP when the display device DD is folded/unfolded. Thus, an interconnect such as a sensing coil passing through the digitizer DGT1 between the center bar CB and the wing plate WP may be physically damaged, which may cause problems of a resistance defect such as an increase in resistance of the interconnect and a degradation in reliability of the display device DD. Hereinafter, the digitizer DGT1 and the display device DD designed to solve the problems will be described.

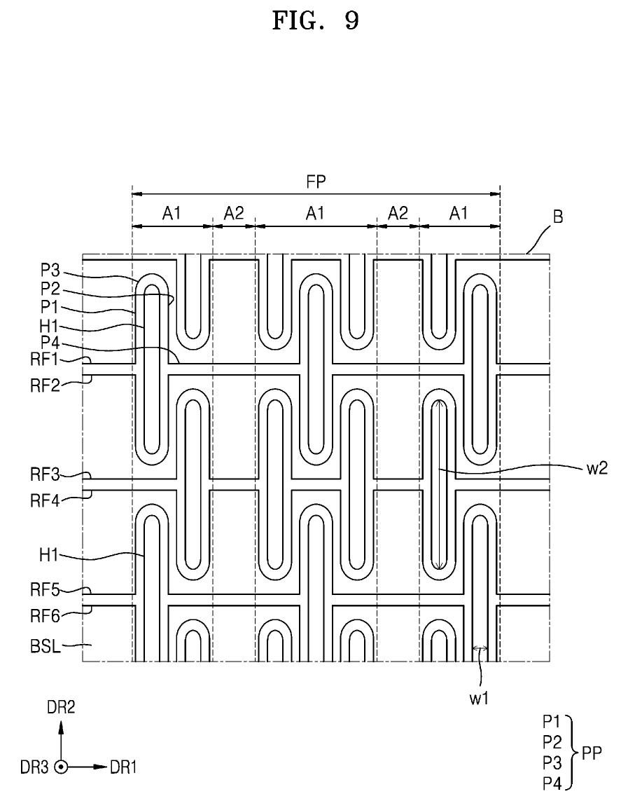

FIG. 9 is a plan view illustrating an example of area B of FIG. 7.

Referring to FIGS. 5, 7 and 9,the through-holes HL may be defined in the folding portion FP of the digitizer DGT1. Each of the through-holes HL may pass through the base layer BSL in a thickness direction (e.g., the third direction DR3).

In an unfolded state of the display device DD, the gap G which is a separation space may be defined between the center bar CB and each of the wing plates WP. In an embodiment, the gap G may have a size of less than or equal to about 0.8 mm.

In an embodiment, the folding portion FP of the digitizer DGT1 may include a first area A1 which is an area that does not overlap the gap G (e.g., in the third direction DR3) and a second area A2 which is an area that overlaps the gap G (e.g., in the third direction DR3).

As the display device DD is repeatedly folded/unfolded, interference may occur due to a phenomenon or the like in which the second area A2 overlapping the gap G in the third direction DR3 in the digitizer DGT1 is caught or pinched between the center bar CB and the wing plate WP. To increase the impact resistance of the second area A2, the elongation of the first area A1 may be greater than that of the second area A2. The “elongation” of an area may refer to a maximum elongation distance or elongation rate of the area when the display device DD is folded or otherwise deformed.

In an embodiment, the through-holes HL may include first holes H1 disposed in the first area A1. The first holes H1 may be disposed in the first area A1 and are arranged to be spaced apart from each other in the second direction DR2. The first holes H1 may be spaced a certain distance apart from each other in the first direction DR1, and as an example, the first holes H1 may be mutually disposed in a zigzag manner in the first direction DR1. Accordingly, the remaining portion of the folding portion FP excluding the through-holes HL may have a lattice-patterned slit shape, and the display device DD may be more smoothly folded along a folding axis extending in the second direction DR2.

In an embodiment, a width w1 of each of the first holes H1 in the first direction DR1 may be less than a width w2 thereof in the second direction DR2 perpendicular to the first direction DR1. Thus, the display device DD may be more smoothly folded along the folding axis extending in the second direction DR2.

As an example, an aperture ratio of the first area A1 may be greater than an aperture ratio of the second area A2. For example, a density of through-holes HL in the first area A1 may be greater than a density of through-holes HL in the second area A2. In an embodiment, the through-hole HL may not be disposed in the second area A2. Thus, the impact resistance of the digitizer DGT1 may be further increased. As an example, a distance between two first holes H1 closest to the gap G in the first direction DR1 may be greater than about 1.4 mm.

In an embodiment, the first hole H1 may be formed through laser processing. For example, the width w1 of the first hole H1 in the first direction DR1 may be less than the width w2 of the first hole H1 in the second direction DR2. Thus, the display device DD may be more smoothly folded along the folding axis extending in the second direction DR2.

In an embodiment, the folding portion FP may include three first areas A1 arranged in the first direction DR1, and although FIG. 9 illustrates that, among columns of the first holes H1 disposed in the first direction DR1, the first area A1 at a middle has three columns, and the first areas A1 at opposite sides of the first area A1 at the middle each have two columns, one or more embodiments are not necessarily limited thereto. For example, the number of columns of the first holes H1 in the first direction DR1 may be adjusted according to a desired size of the folding portion FP, sizes of the first holes H1, and the like.

The first non-folding portion NFP1 and the second non-folding portion NFP2 may have substantially identical or symmetrical shapes. Therefore, hereinafter, the first non-folding portion NFP1 will be mainly described for economy of explanation. The description of the first non-folding portion NFP1 may apply to the description of the second non-folding portion NFP2.

The first sensing coils RF may be disposed in the first non-folding portion NFP1 and the folding portion FP. In FIG. 9, coils RF1, RF2, RF3, RF4, RF5, and RF6 forming different loops among the first sensing coils RF are illustrated as an example. Each of the first sensing coils RF may extend to pass between the first holes H1 in the folding portion FP. In an embodiment, each of the first sensing coils RF may be bent (e.g., have a bent configuration in a plan view) and extend along edges of the first holes H1 in the folding portion FP.

In an embodiment, each of the first sensing coils RF may include a pattern portion PP in the folding portion FP. In an embodiment, the pattern portion PP may include a first pattern P1, a second pattern P2, a third pattern P3, and a fourth pattern P4.

In an embodiment, each of the first pattern P1 and the second pattern P2 may extend in the second direction DR2. The first pattern P1 and the second pattern P2 may be spaced apart from each other in the first direction DR1, and one first hole H1 may be disposed between the first pattern P1 and the second pattern P2. The first and second patterns P1 and P2 may surround at least a portion of the first hole H1 in a plan view.

The third pattern P3 may connect the first pattern P1 to the second pattern P2. In an embodiment, the third pattern P3 may have curvature. The third pattern P3 may surround an end of the first hole H1 in a plan view (e.g., an upper end in the second direction DR2).

The fourth pattern P4 may extend from the second pattern P2 in the first direction DR1. The fourth pattern P4 may be connected to the first pattern P1 of another pattern portion PP included in the same first sensing coils RF.

Accordingly, the pattern portion PP may be disposed between adjacent first holes H1.

As shown in FIG. 9, the first and second patterns P1 and P2 may have a shape of a straight line extending in the second direction DR2, and the fourth pattern P4 may have a shape of a straight line extending in the first direction DR1, but embodiments of the present disclosure are not necessarily limited thereto. For example, in some embodiments one or more of the first, second, and fourth patterns P1, P2, and P4 may have curvature like the third pattern P3.

The digitizer DGT1 according to an embodiment of the present disclosure may include the folding portion FP, in which the through-holes HL are defined, and the first sensing coils RF extending along the edges of the through-holes HL.

For example, in the folding portion FP of the digitizer DGT1, the first holes H1 may be disposed in the first area A1, and the through-holes HL may not be disposed in the second area A2 so that, even when the display device DD is repeatedly folded/unfolded, the impact resistance of the folding portion FP may be increased and the reliability of a circuit interconnect disposed in the folding portion FP may be increased.

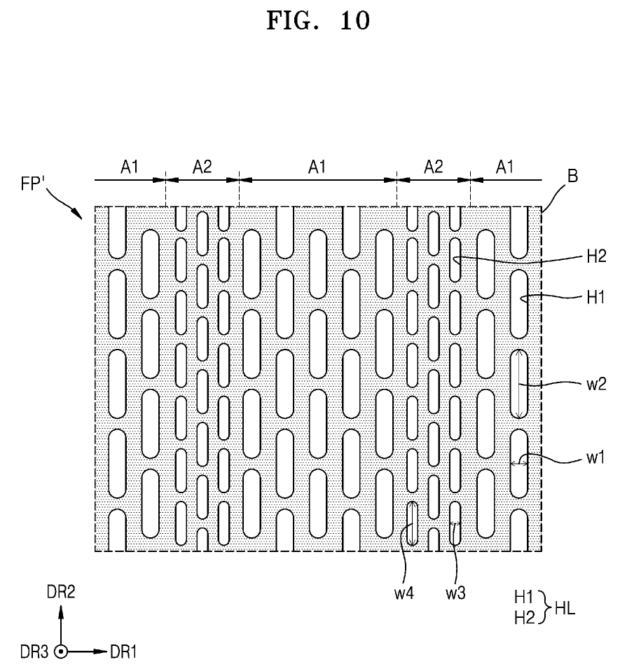

FIG. 10 is a schematic plan view illustrating another example of area B of FIG. 7.

Referring to FIGS. 5 and 10, the through-holes HL may be defined in a folding portion FP’ of the digitizer DGT1. Each of the through-holes HL may pass through the digitizer DGT1 in the thickness direction (e.g., the third direction DR3).

In an unfolded state of the display device DD, the gap G which is a separation space may be defined between the center bar CB and each of the wing plates WP. In an embodiment, the gap G may have a size of less than or equal to about 0.8 mm (e.g., in the first direction DR1).

In an embodiment, the folding portion FP’ of the digitizer DGT1 may include a first area A1 which is an area that does not overlap the gap G (e.g., in the third direction DR3) and a second area A2 which is an area that overlaps the gap G (e.g., in the third direction DR3).

As the display device DD is repeatedly folded/unfolded, interference may occur due to a phenomenon or the like in which the second area A2 overlapping the gap G in the third direction DR3 in the digitizer DGT1 is caught or pinched between the center bar CB and the wing plate WP. To increase the impact resistance of the second area A2, the elongation (e.g., a maximum elongation distance or elongation rate) of the first area A1 may be greater than that of the second area A2.

The through-holes HL may include first holes H1 disposed in the first area A1. The first holes H1 may be disposed in the first area A1 and may be arranged to be spaced apart from each other in the second direction DR2. The first holes H1 may be spaced a certain distance apart from each other in the first direction DR1, and as an example, in an embodiment the first holes H1 may be mutually disposed in a zigzag manner in the first direction DR1. Accordingly, the remaining portion of the folding portion FP’ excluding the through-holes HL may have a lattice-patterned slit shape, and the display device DD may be more smoothly folded along the folding axis extending in the second direction DR2.

In an embodiment, each of the first holes H1 may have a width w1 in the first direction DR1 that is less than a width w2 in the second direction DR2 perpendicular to the first direction DR1. Thus, the display device DD may be more smoothly folded along the folding axis extending in the second direction DR2.

As an example, an aperture ratio of the first area A1 may be greater than an aperture ratio of the second area A2. In an embodiment, the through-holes HL may include second holes H2 disposed in the second area A2.

The second hole H2 may be different from the first hole H1. For example, the second hole H2 may have at least one of a different size (e.g., area in a plan view) and shape (e.g., in a plan view) as compared to the first hole H1. As an example, the second holes H2 may have the same shape as the first holes H1 (e.g., in a plan view), but a size of the second hole H2 (e.g., area in a plan view) may be less than a size of the first hole H1 (e.g., area in a plan view). As an example, a width w3 of the second hole H2 in the first direction DR1 may be less than the width w1 of the first hole H1 in the first direction DR1, and a width w4 of the second hole H2 in the second direction DR2 may be less than the width w2 of the first hole H1 in the second direction DR2.

In the folding portion FP’, the second holes H2 smaller than the first hole H1 may be disposed in the second area A2 so that elongation (e.g., a maximum elongation distance or elongation rate) in the second area A2 may be less than that in the first area A1, and the impact resistance of the digitizer DGT1 may be further increased. Thus, even when the display device DD is repeatedly folded/unfolded, a phenomenon in which the second area A2 is physically damaged and a problem in that the resistance of an interconnect such as a sensing coil disposed in the second area A2 is increased may be alleviated and prevented, and the reliability of the display device DD may be increased.

As described with reference to FIG. 9, the number of columns of the first holes H1 or columns of the second holes H2 disposed in the first direction DR1 in each of the first area A1 and the second area A2 is not necessarily limited to that shown in FIG. 10, and the number of columns of the first holes H1 and the second holes H2 in the first direction DR1 may be adjusted according to a desired size of the folding portion FP’, sizes of the first holes H1 and the second holes H2, and the like.

Although the sensing coils are not shown in FIG. 10 for convenience, as shown in FIG. 9, the sensing coils may be bent and extended along edges of the second holes H2 between the second holes H2 as well as between the first holes H1 in the same manner that the sensing coils are bent and extended between the first holes H1 shown and described in FIG. 9.

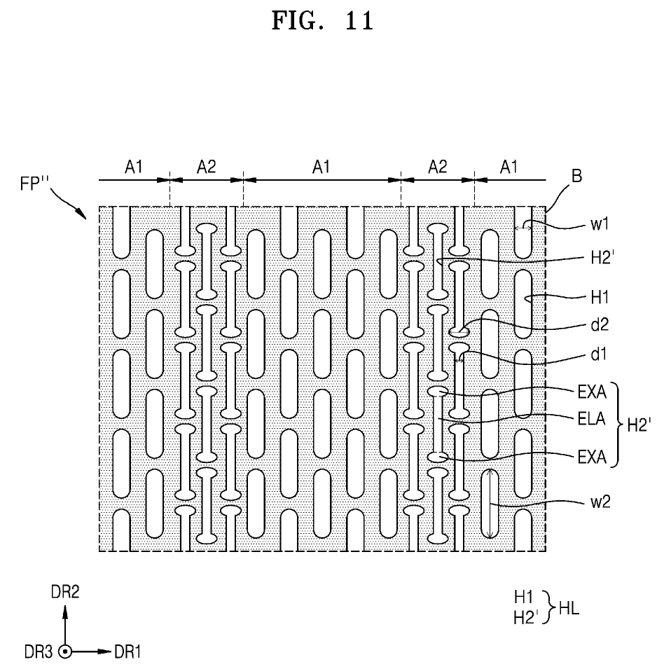

FIG. 11 is a schematic plan view illustrating another example of area B of FIG. 7.

Referring to FIGS. 5 and 11, the through-holes HL may be defined in a folding portion FP’’ of the digitizer DGT1. Each of the through-holes HL may pass through the digitizer DGT1 in the thickness direction (e.g., the third direction DR3).

In an unfolded state of the display device DD, the gap G which is a separation space may be defined between the center bar CB and each of the wing plates WP. As an example, in an embodiment the gap G may have a size of less than or equal to about 0.8 mm e.g., in the first direction DR1).

In an embodiment, the folding portion FP’’ of the digitizer DGT1 may include a first area A1 which is an area that does not overlap the gap G (e.g., in the third direction DR3) and a second area A2 which is an area that overlaps the gap G (e.g., in the third direction DR3).

As the display device DD is repeatedly folded/unfolded, interference may occur due to a phenomenon or the like in which the second area A2 overlapping the gap G in the third direction DR3 in the digitizer DGT1 is caught or pinched between the center bar CB and the wing plate WP. To increase the impact resistance of the second area A2, the elongation (e.g., a maximum elongation distance or elongation rate) of the first area A1 may be greater than that of the second area A2.

The through-holes HL may include first holes H1 disposed in the first area A1. The first holes H1 may be disposed in the first area A1 and arranged to be spaced apart from each other in the second direction DR2. In an embodiment, the first holes H1 may be spaced a certain distance apart from each other in the first direction DR1, and as an example, the first holes H1 may be mutually disposed in a zigzag manner in the first direction DR1. Accordingly, the remaining portion of the folding portion FP’’ excluding the through-holes HL may have a lattice-patterned slit shape, and the display device DD may be more smoothly folded along the folding axis extending in the second direction DR2.

In an embodiment, each of the first holes H1 may have a width w1 in the first direction DR1 that is less than a width w2 in the second direction DR2 perpendicular to the first direction DR1. Thus, the display device DD may be more smoothly folded along the folding axis extending in the second direction DR2.

As an example, an aperture ratio of the first area A1 may be greater than an aperture ratio of the second area A2. In an embodiment, the through-holes HL may include second holes H2’ disposed in the second area A2.

The second hole H2’ may be different from the first hole H1. As an example, the second holes H2’ may have a different shape (e.g., in a plan view) from the first holes H1. A size (e.g., area in a plan view) of the second hole H2’ may be less than a size (e.g., area in a plan view) of the first hole H1.

In an embodiment, each of the second holes H2’ may include an extension portion ELA extending in the second direction DR2 perpendicular to the first direction DR1 and expansion portions EXA disposed at opposite ends of the extension portion ELA. In some embodiments, the extension portion ELA may extend in the second direction DR2, and the expansion portions EXA may be defined at a first end of the extension portion ELA and a second end opposite to the first end (e.g., a side opposite to the first end), respectively. For example, in one second hole H2’, the expansion portions EXA may be spaced apart from each other in the second direction DR2, and the extension portion ELA may connect the expansion portions EXA to each other.

In an embodiment, a planar shape of the extension portion ELA may be different from a planar shape of each of the expansion portions EXA. For example, the planar shapes of the expansion portions EXA may be substantially identical or similar to each other. In an embodiment, at least a portion of each of the expansion portion EXA may have curvature. For example, each of the expansion portions EXA may be defined as a circular planar shape. As an example, in an embodiment the expansion portions EXA may have at least one planar shape of a circular shape, an elliptical shape, a triangular shape, or a quadrangular shape. However, embodiments of the present disclosure are not necessarily limited thereto, and the planar shape of each of the expansion portions EXA may be changed in various ways.

In an embodiment, a width of at least one area of each of the expansion portions EXA in the first direction DR1 may be greater than a width of the extension portion ELA. A maximum width d2 of the expansion portion EXA in the first direction DR1 may be greater than a width d1 of the extension portion ELA in the first direction DR1. The maximum width d2 of the expansion portion EXA in the first direction DR1 may be less than the width w1 of the first hole H1 in the first direction DR1. Thus, when the folding portion FP’’ of the digitizer DGT1 is folded, tearing of the second area A2 may be prevented, and impact resistance may be increased.

In an embodiment, the extension portion ELA may be formed through minimum laser processing. The width d1 of the extension portion ELA in the first direction DR1 may be defined as a width of a laser beam that may be generated through one-time laser processing. For example, in an embodiment the width d1 of the extension portion ELA in the first direction DR1 may be in a range of 0 millimeter (mm) to about 0.15 mm. However, embodiments of the present disclosure are not necessarily limited thereto, and the width d1 of the extension portion ELA in the first direction DR1 may be changed according to a laser that may be used for laser processing.

As an example, in an embodiment the maximum width d2 of the expansion portion EXA in the first direction DR1 may be greater than the width d1 of the extension portion ELA in the first direction DR1 in a range of 0 mm to about 0.9 mm or more.

By arranging the second holes H2’ as described above in the second area A2, elongation (e.g., a maximum elongation distance or elongation rate) in the second area A2 may be less than that in the first area A1, and the impact resistance of the digitizer DGT1 may be further increased. Thus, even when the display device DD is repeatedly folded/unfolded, a phenomenon in which the second area A2 is physically damaged and a problem in that the resistance of an interconnect such as a sensing coil disposed in the second area A2 is increased may be alleviated and prevented, and the reliability of the display device DD may be increased.

As described with reference to FIG. 9, the number of columns of the first holes H1 or columns of the second holes H2’ disposed in the first direction DR1 in each of the first area A1 and the second area A2 is not necessarily limited to that shown in FIG. 11, and the number of columns of the first holes H1 and the second holes H2 in the first direction DR1 may be adjusted according to a desired size of the folding portion FP’’, sizes of the first holes H1 and the second holes H2’, and the like.

Although the sensing coils are not shown in FIG. 11 for convenience, as shown in FIG. 9, sensing coils may be bent (e.g., have a bent configuration in a plan view) and extend along edges of the second holes H2’ between the second holes H2’ as well as between the first holes H1 in the same manner that the sensing coils are bent and extend between the first holes H1 shown and described in FIG. 9.

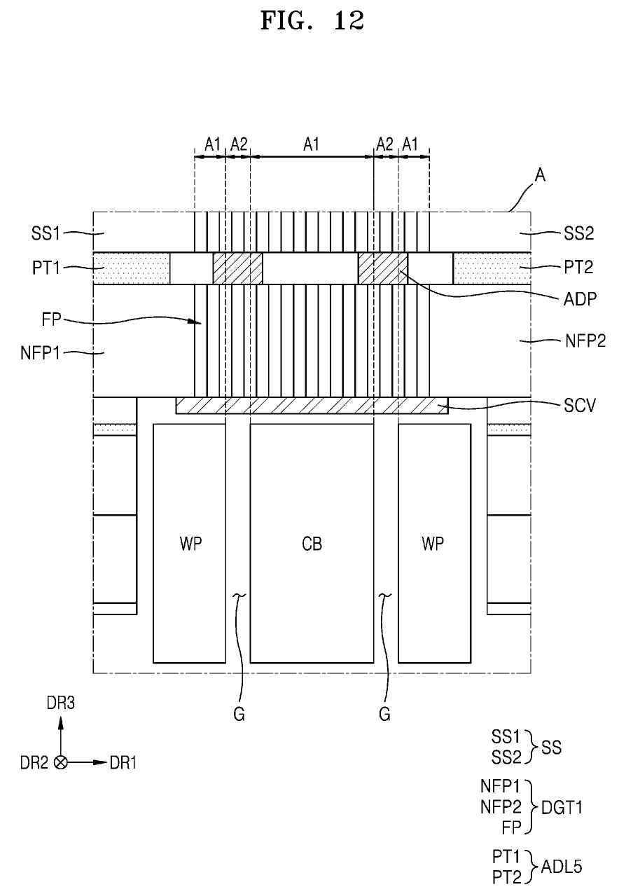

FIG. 12 is a schematic cross-sectional view illustrating an example of area A of FIG. 5.

Referring to FIG. 12, the display device DD may further include the adhesive portion ADP between the panel support SS and the digitizer DGT1. In an unfolded state of the display device DD, the gap G which is a separation space may be defined between the center bar CB and each of the wing plates WP.

As an example, the adhesive portion ADP may be disposed to overlap at least the gap G in the third direction DR3 which is the thickness direction of the display panel DP. Thus, a phenomenon in which in the second area A2 is caught and pinched between the wing plate WP and the center bar CB may be alleviated and prevented, and the impact resistance of the digitizer DGT1 may be increased.

The adhesive portion ADP overlapping the gap G may be in the form of an island. As an example, the adhesive portions ADP overlapping the gaps G may be spaced apart from each other. The adhesive portion ADP may not be disposed in one area overlapping the first area A1 in the third direction DR3 on the same plane as the adhesive portion ADP, thereby securing the foldability of the digitizer DGT1 and the panel support SS.

In an embodiment, the first portion PT1 of the fifth adhesive layer ADL5 is disposed between the first panel support SS1 and the first non-folding portion NFP1 (e.g., in the third direction DR3), and the second portion PT2 of the fifth adhesive layer ADL5 is disposed between the second panel support SS2 and the second non-folding portion NFP2 (e.g., in the third direction DR3), wherein the first portion PT1 and the second portion PT2 are spaced apart from each other, and each adhesive portion ADP is also spaced apart from the first portion PT1 and the second portion PT2.

The adhesive portion ADP may include the same material as the fifth adhesive layer ADL5 positioned on the same plane as the adhesive portion ADP and may have a modulus that is higher or lower than a modulus of the fifth adhesive layer ADL5.

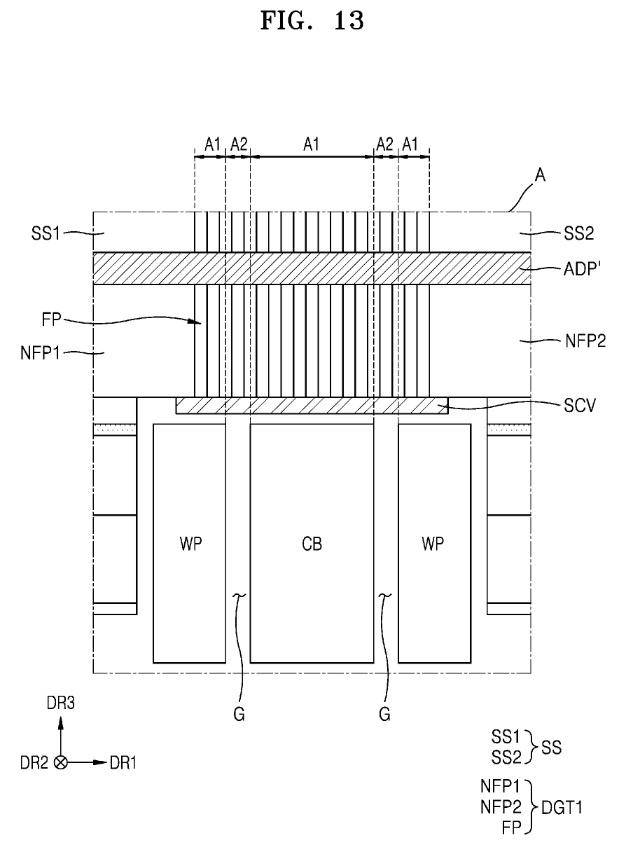

FIG. 13 is a schematic cross-sectional view illustrating another example of area A of FIG. 5.

Referring to FIG. 13, the display device DD may further include an adhesive portion ADP’ between the panel support SS and the digitizer DGT1 (e.g., in the third direction DR3). In an unfolded state of the display device DD, the gap G which is a separation space may be defined between the center bar CB and each of the wing plates WP.

As an example, the adhesive portion ADP’ may be disposed to overlap at least the folding portion FP in the third direction DR3 which is the thickness direction of the display panel DP. As an example, the adhesive ADP’ may have a lower modulus than other adhesive layers. For example, in an embodiment the modulus of the adhesive ADP’ may be less than or equal to about 0.2 MPa at a temperature of -20 ˚C. Thus, it is possible to alleviate and prevent sagging of the folding portion FP and alleviate and prevent interference occurrence and circuit failure in the second area A2 between the wing plate WP and the center bar CB caused by the display device DD being repeatedly folded/unfolded.

As an example, the adhesive portion ADP’ may be formed integrally with the fifth adhesive layer ADL5 which is disposed between the panel support SS and the digitizer DGT1 and is disposed on the same plane as the adhesive portion ADP’. For example, the adhesive portion ADP’ may include the same material as the fifth adhesive layer ADL5.

Due to the adhesive portion ADP’ having a low modulus and an integral layered shape, a phenomenon in which in the second area A2 is caught and pinched between the wing plate WP and the center bar CB may be alleviated and prevented, and the reliability of the display device DD may be increased.

The display device DD according to embodiments of the present disclosure may be applied to various electronic apparatuses 1000. The electronic apparatus 1000 according to an embodiment may include the display device DD described above and may further include a module or device having additional functions in addition to the display device DD.

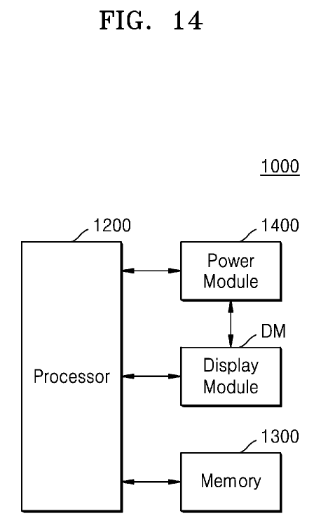

FIG. 14 is a block diagram of the electronic apparatus 1000 according to an embodiment of the present disclosure. Referring to FIG. 14, the electronic apparatus 1000 according to an embodiment may include a display module DM, a processor 1200, a memory 1300, and a power module 1400.

The processor 1200 may include at least one of a central processing unit (CPU), an application processor (AP), a graphic processing unit (GPU), a communication processor (CP), an image signal processor (ISP), or a controller.

The memory 1300 may store data information required for the operation of the processor 1200 or the display module DM. When the processor 1200 executes an application stored in the memory 1300, an image data signal and/or an input control signal may be transmitted to the display module DM, and the display module DM may process a received signal to output image information through a display screen.

The power module 1400 may include a power supply module such as a power adapter or a battery device, and a power conversion module that converts power supplied by the power supply module to generate power required for the operation of the electronic apparatus 1000.

At least one of the components of the above-described electronic apparatus 1000 may be included in the above-described display device DD according to the embodiments. In addition, some of individual modules functionally included in one module may be included in the display device DD, and others may be provided separately from the display device DD. For example, the display device DD may include the display module DM, and the processor 1200, the memory 1300, and the power module 1400 may be provided in the form of other devices within the electronic apparatus 1000 other than the display device DD.

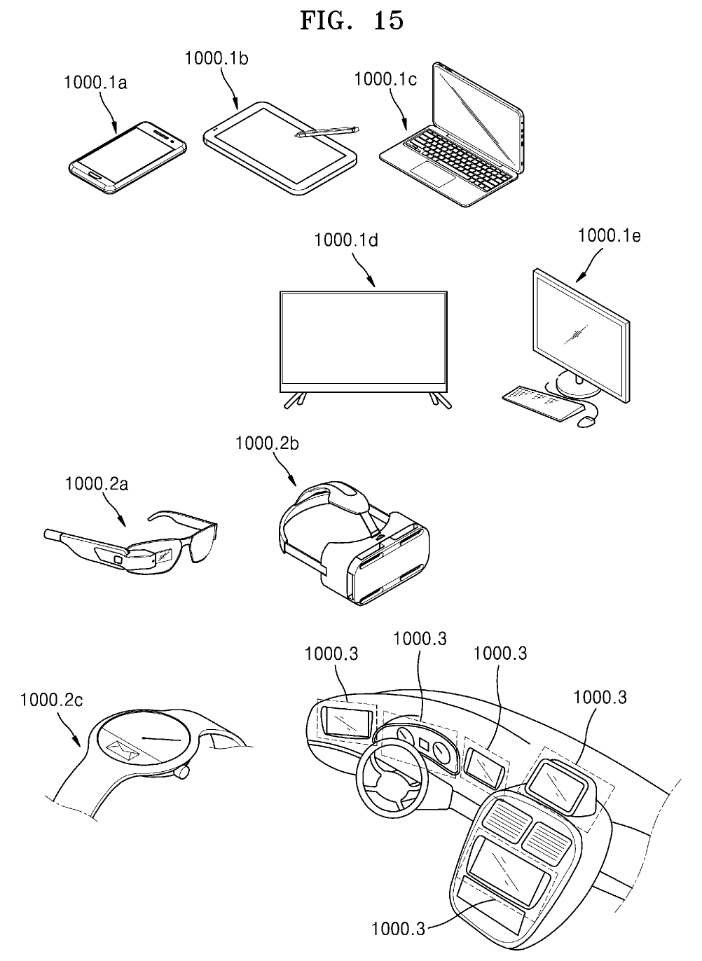

FIG. 15 shows schematic views of electronic apparatuses according to various embodiments.

Referring to FIG. 15, various electronic apparatuses to which a display device DD according to embodiments is applied may include not only image display electronic apparatuses such as a smartphone 1000.1a, a tablet personal computer (PC) 1000.1b, a laptop personal computer 1000.1c, a television (TV) 1000.1d, a desk monitor 1000.1e, but also wearable electronic apparatuses including a display module, such as smart glasses 1000.2a, a head-mounted display 1000.2b, and a smart watch 1000.2c, and vehicle electronic apparatuses 1000.3 including a display module, such as a center information display (CID) disposed on a dashboard, a center fascia, or a dashboard of a vehicle, and a room mirror display. However, the display device DD may be applied to various other small-sized, medium-sized or large-sized electronic devices.

Each of the embodiments described above may be implemented independently, but of course, the structures of each embodiment may be applied in combination to other embodiments.

While the present disclosure has been described with reference to embodiments illustrated in the drawings, this is merely illustrative. It is to be understood that various equivalent modifications and variations of the embodiments may be made by a person having an ordinary skill in the art without departing from the spirit and scope of the present disclosure.

The specific implementations described in the embodiments are examples and do not limit the scope of the embodiments in any method. In addition, unless “essential,” “important,” and the like are not specifically mentioned, it may not be a necessary component for the application of the present disclosure.

In the specification of embodiments, the use of the term “the” and similar indicating terms may correspond to both singular and plural. In addition, in the case where a range is described in an embodiment, since it includes the disclosure in which the individual values belonging to the range are applied, unless otherwise stated, it is the same as describing each individual value constituting the range in the detailed description. Finally, when there is no explicit or contradictory description of operations constituting the method according to the embodiment, the operations may be performed in a suitable order. The embodiments are not necessarily limited to the order in which the operations are described. The use of all the examples or terms in the embodiments is merely for describing the embodiments in detail. Accordingly, the scope of the embodiments may not be limited by the examples or terms. In addition, those skilled in the art may recognize that various modifications, combinations, and changes may be confided according to design conditions and factors within the scope of the appended claims or equivalents thereof.

According to embodiments of the present disclosure, there may be provided a display device which is easily folded during a folding operation and has increased reliability, and an electronic apparatus including the same.

However, the effects that may be achieved through the present disclosure are not limited to the above-described effects, and other technical effects that are not described herein will be clearly understood by those skilled in the art from the following portion descriptions of the present disclosure.

What is claimed is:

1. A display device comprising:
a display panel;
a digitizer having a first side disposed on a side surface of the display panel, the digitizer comprising a folding portion;
a panel support between the display panel and the digitizer in a thickness direction of the display panel;
a center bar positioned at a second side of the digitizer opposite to the first side of the digitizer, the center bar is positioned to overlap the folding portion in the thickness direction of the display panel; and
wing plates respectively disposed at opposite sides of the center bar in a first direction crossing the thickness direction of the display panel,
wherein a gap comprising a separation space is defined between the center bar and each of the wing plates, and
the folding portion comprises
a first area including first holes; and
a second area overlapping the gap in the thickness direction of the display panel.

2. The display device of claim 1, wherein a maximum elongation distance of the first area when the display device is folded is greater than a maximum elongation distance of the second area when the display device is folded.

3. The display device of claim 2, wherein the second area includes second holes having at least one of a different size and shape in a plan view from the first holes.

4. The display device of claim 3, wherein:
a width of each of the first holes in the first direction is less than a width of each of the first holes in a second direction crossing the first direction; and
the second holes have a same shape as the first holes and an area in the plan view of the second holes is less than an area in the plan view of the first holes.

5. The display device of claim 3, wherein:
each of the second holes comprises an extension portion extending in a second direction crossing the first direction and expansion portions disposed at opposite ends of the extension portion; and
in the first direction, a width of at least one area of each of the expansion portions is greater than a width of the extension portion.

6. The display device of claim 5, wherein the expansion portions have at least one planar shape of a circular shape, an elliptical shape, a triangular shape, or a quadrangular shape.

7. The display device of claim 1, wherein an aperture ratio of the first area is greater than an aperture ratio of the second area.

8. The display device of claim 1, further comprising an adhesive portion disposed between the panel support and the digitizer,
wherein the adhesive portion is disposed to overlap at least the gap in the thickness direction of the display panel.

9. The display device of claim 8, wherein:
the adhesive portion overlaps at least the folding portion in the thickness direction of the display panel; and
a modulus of the adhesive portion is less than or equal to about 0.2 MPa.

10. The display device of claim 1, wherein the digitizer comprises sensing coils disposed between adjacent first holes.

11. A display device comprising:
a display panel;
a digitizer having a first side disposed on a side surface of the display panel, the digitizer comprising a folding portion;
a panel support between the display panel and the digitizer in a thickness direction of the display panel;
an adhesive portion disposed between the panel support and the digitizer;
a center bar positioned at a second side of the digitizer opposite to the first side of the digitizer, the center bar is positioned to overlap the folding portion in the thickness direction of the display panel; and
wing plates respectively disposed at opposite sides of the center bar in a first direction crossing the thickness direction of the display panel,
wherein a gap comprising a separation space is defined between the center bar and each of the wing plates, and
the adhesive portion is disposed to overlap at least the gap in the thickness direction of the display panel.

12. The display device of claim 11, wherein the adhesive portion overlaps at least the folding portion in the thickness direction of the display panel, and
a modulus of the adhesive portion is less than or equal to about 0.2 MPa.

13. The display device of claim 11, wherein the folding portion comprises a first area including first holes and a second area overlapping the gap in the thickness direction of the display panel.

14. The display device of claim 13, wherein a maximum elongation distance of the first area when the display device is folded is greater than a maximum elongation distance of the second area when the display device is folded.

15. The display device of claim 14, wherein second holes are disposed in the second area, the second holes having at least one of a different size and shape in a plan view from the first holes.

16. The display device of claim 15, wherein a width of each of the first holes in the first direction is less than a width of each of the first holes in a second direction crossing the first direction, and
the second holes have a same shape as the first holes and have an area in the plan view that is less than an area in the plan view of the first holes.

17. The display device of claim 15, wherein each of the second holes comprises an extension portion extending in a second direction crossing the first direction and expansion portions disposed at opposite ends of the extension portion, and
a width of at least one area of each of the expansion portions is greater than a width of the extension portion in the first direction.

18. The display device of claim 17, wherein the expansion portions have at least one planar shape of a circular shape, an elliptical shape, a triangular shape, or a quadrangular shape.

19. The display device of claim 13, wherein an aperture ratio of the first area is greater than an aperture ratio of the second area.

20. An electronic device comprising:
a display device;
a memory storing data information;
a processor configured to transmit the data information to the display device; and
a power module configured to supply and generate power,
wherein the display device comprises a display panel, a digitizer having a first side disposed on a side surface of the display panel, the digitizer comprising a folding portion, a panel support between the display panel and the digitizer in a thickness direction of the display panel, a center bar positioned at a second side of the digitizer opposite to the first side of the digitizer, the center bar is positioned to overlap the folding portion in the thickness direction of the display panel, and wing plates respectively disposed at opposite sides of the center bar in a first direction crossing the thickness direction of the display panel,
a gap comprising a separation space is defined between the center bar and each of the wing plates, and
the folding portion comprises a first area including first holes and a second area overlapping the gap in the thickness direction of the display panel.
